(19) United States
(12) Patent Application Publication
(10) Pub. No.: US 2021/0165151 A1
(43) Pub. Date: Jun. 3, 2021

(54) OPTICAL ELEMENT, PRODUCTION METHOD THEREOF, AND PROJECTION IMAGE DISPLAY DEVICE

(71) Applicant: DEXERIALS CORPORATION, Tokyo (JP)

(72) Inventors: Junichi SUGAWARA, Tokyo (JP); Masatoshi SASAKI, Tokyo (JP); Hironori OSHIMA, Tokyo (JP); Junichi MIZUMA, Tokyo (JP)

(73) Assignee: DEXERIALS CORPORATION, Tokyo (JP)

(21) Appl. No.: 17/105,739

(22) Filed: Nov. 27, 2020

(30) Foreign Application Priority Data
Nov. 28, 2019 (JP) 2019-215090

(51) Int. Cl. G02B 5/30; C23C 14/22

(52) U.S. Cl. CPC G02B 5/3083; G02F 1/13363; C23C 14/226

(57) ABSTRACT

An optical element including a substrate that is transparent to light at a using wavelength band, an antireflection layer, a matching layer, and a birefringent layer formed of an oblique angle vapor deposition film, wherein an optical loss in the optical element at the using wavelength band is 1.0% or less, and the optical loss is calculated using the following formulae from intensity of transmitted light and intensity of reflected light measured by S-polarized light at an incident angle of 5° in the optical element,

Transmittance=intensity of transmitted light/intensity of incident light (%)

Reflectance=intensity of reflected light/intensity of incident light (%)

Optical loss (%)=100%−transmittance (%)−reflectance (%).

### CROSS-REFERENCE TO RELATED APPLICATIONS

This application claims priority to Japanese application No. 2019-215090, filed on Nov. 28, 2019 and incorporated herein by reference.

### BACKGROUND OF THE INVENTION

### Field of the Invention

The present invention relates to an optical element, a production method thereof, and a projection image display device.

### Description of the Related Art

As a light source used for a projector, a laser light source capable of emitting light of high luminance with high output has been prominent.

Conventionally, an optical element formed of an oblique angle vapor deposition film (see, for example, Japanese Patent Application Laid-Open (JP-A) No. 2012-256024).

However, there is a problem that such an optical element is deteriorated by light emitted from a laser light source.

### SUMMARY OF THE INVENTION

<1> An optical element, including:
a substrate that is transparent to light at a using wavelength band;
an antireflection layer;
a matching layer; and
a birefringent layer formed of an oblique angle vapor deposition film,
wherein an optical loss in the optical element at the using wavelength band is 1.0% or less, and
the optical loss is calculated using the following formulae from intensity of transmitted light and intensity of reflected light measured by S-polarized light at an incident angle of 5° in the optical element,

Transmittance=intensity of transmitted light/intensity of incident light (%)

Reflectance=intensity of reflected light/intensity of incident light (%)

Optical loss (%)=100%−transmittance (%)−reflectance (%).

<2> The optical element according to <1>,
wherein the optical loss in the optical element at a wavelength of 455 nm is 1.0% or less.
<3> The optical element according to <1>,
wherein the antireflection layer is a multilayer film in which two or more inorganic oxide films having mutually different refractive indexes are deposited.
<4>The optical element according to <3>,
wherein at least one of the inorganic oxide films includes at least one selected from the group consisting of Ti, Si, Ta, Al, Ce, Zr, Nb, and Hf.
<5> The optical element according to <4>,
wherein at least one of the inorganic oxide films includes Nb.
<6> The optical element according to <4>,
wherein at least one of the inorganic oxide films includes Si.
<7> The optical element according to <4>,
wherein the antireflection layer is a multilayer film in which an inorganic oxide film including Nb and an inorganic oxide film including Si are deposited.
<8> The optical element according to <1>,
wherein the matching layer is a multilayer film in which two or more inorganic oxide films having mutually different refractive indexes are deposited.
<9> The optical element according to <8>,
wherein at least one of the inorganic oxide films includes at least one selected from the group consisting of Ti, Si, Ta, Al, Ce, Zr, Nb, and Hf.
<10> The optical element according to <9>,
wherein at least one of the inorganic oxide films includes Nb.
<11> The optical element according to <9>,
wherein at least one of the inorganic oxide films includes Si.
<12> The optical element according to <9>,
wherein the matching layer is a multilayer film in which an inorganic oxide film including Nb and an inorganic oxide film including Si are deposited.
<13> The optical element according to <1>,
wherein the antireflection layer is disposed on both sides of the substrate.
<14> A production method of an optical element, including:
providing a substrate that is transparent to light at a using wavelength band;
forming at least one antireflection layer;
forming a matching layer; and
forming a birefringent layer formed of an oblique angle vapor deposition film,
wherein an optical loss in the optical element at the using wavelength band is 1.0% or less,
the antireflection layer or the matching layer, or both are formed by reactive sputtering, and
the optical loss is calculated using the following formulae from intensity of transmitted light and intensity of reflected light measured by S-polarized light at an incident angle of 5° in the optical element,

Transmittance=intensity of transmitted light/intensity of incident light (%)

Reflectance=intensity of reflected light/intensity of incident light (%)

Optical loss (%)=100%−transmittance (%)−reflectance (%).

<15> The production method according to <14>,
wherein the reactive sputtering is reactive sputtering using mixed gas including inert gas and oxygen gas, and
an oxygen flow ratio in the mixed gas is set in a manner that the optical loss of the optical element is to be 1.0% or less relative to the light at the using wavelength band.
<16> The production method according to <14>,
wherein the forming at least one antireflection layer, the forming a matching layer, or both include laminating two or more inorganic oxide films having mutually different refractive indexes by reactive sputtering to form a multilayer film.
<17> The production method according to <14>,
wherein the forming at least one antireflection layer or the forming a matching layer, or both include forming an oxide film including Nb using mixed gas including inert gas and oxygen gas by reactive sputtering using Nb as a target, and
wherein an oxygen flow ratio in the mixed gas is greater than 18% when the oxide film including Nb is formed, where the oxygen flow ratio is represented by [an oxygen flow rate/(an inert gas flow rate+the oxygen gas flow rate)].
<18> The production method according to <14>,
wherein the forming at least one antireflection layer or the forming a matching layer, or both include forming an oxide film including Si using mixed gas including inert gas and oxygen gas by reactive sputtering using Si as a target, and
wherein an oxygen flow ratio in the mixed gas is greater than 8% when the oxide film including Si is formed, where the oxygen flow ratio is represented by [an oxygen flow rate/(an inert gas flow rate+the oxygen gas flow rate)].
<19> A projection image display device, including:
an optical element;
a light modulator;
a light source configured to emit light; and
a projection optical system configured to project modulated light,
wherein the light modulator and the optical element are disposed on a light path between the light source and the projection optical system, and
wherein the optical element includes:
a substrate that is transparent to light at a using wavelength band;
an antireflection layer;
a matching layer; and
a birefringent layer formed of an oblique angle vapor deposition film,
wherein an optical loss in the optical element at the using wavelength band is 1.0% or less, and
the optical loss is calculated using the following formulae from intensity of transmitted light and intensity of reflected light measured by S-polarized light at an incident angle of 5° in the optical element,

Transmittance=intensity of transmitted light/intensity of incident light (%)

Reflectance=intensity of reflected light/intensity of incident light (%)

Optical loss (%)=100%−transmittance (%)−reflectance (%).

### BRIEF DESCRIPTION OF THE DRAWINGS

FIG. 1 is a cross-sectional view illustrating a configuration example of an optical element;

FIG. 2 is a schematic cross-sectional view of an antireflection layer;

FIG. 3 is a perspective schematic view of an oblique angle vapor deposition film;

FIG. 4 is a schematic view illustrating one example of an oblique angle vapor deposition for forming an oblique angle vapor deposition film;

FIG. 5 is a schematic view illustrating one example of a direction in which a deposition direction from a deposition source is projected towards a deposition target surface;

FIG. 6 is a flowchart illustrating a production method of an optical element;

FIG. 7 is a schematic view illustrating one example of a structure of a projection image display device;

FIG. 8 is a view assisting descriptions of measuring methods of transmittance and reflectance;

FIG. 9A is a graph depicting one transmittance of the sample of Example 1;

FIG. 9B is a graph depicting one reflectance of the sample of Example 1;

FIG. 9C is a graph depicting one optical loss of the sample of Example 1;

FIG. 10A is a graph depicting one transmittance of the sample of Comparative Example 1;

FIG. 10B is a graph depicting one reflectance of the sample of Comparative Example 1; and

FIG. 10C is a graph depicting one optical loss of the sample of Comparative Example 1.

### DESCRIPTION OF THE EMBODIMENTS

Embodiments of the present technology will be described in details according to the following order with reference to drawings.

1. Optical element
2. Production method of optical element
3. Projection image display device

### 4. Examples

The present invention can solve the above-described various problems existing in the art, and can achieve the following object. Specifically, the present invention has an object to provide an optical element having excellent durability even when a laser light source is used, a production method of the optical element, and a projection image display device including the optical element.

The present invention can solve the above-described various problems, in the art, and can provide an optical element having excellent durability even when a laser light source is used, a production method of the optical element, and a projection image display device including the optical element.

### Optical Element

The optical element according to the present embodiment includes a substrate transparent to light at a using wavelength band, an antireflection layer, a matching layer, and a birefringent layer formed of an oblique angle vapor deposition film. The optical element may further include other members according to the necessary.

The optical element has an optical loss of 1.0 or less relative to light at a using wavelength band.

The optical loss is a value obtained by subtracting transmittance to the light at the using wavelength band and reflectance to the light at the using wavelength band from 100%, and is represented by the following formula (1).

Optical loss (%)=100%−transmittance (%)−reflectance (%) Formula (1)

The lower limit of the optical loss is not particularly limited and may be appropriately selected depending on the intended purpose. As the optical loss reduces, productivity may declines. Accordingly, the optical loss may be 0.1% or greater, 0.3% or greater, or 0.5% or greater.

The light at the using wavelength band may be, for example, light in a wavelength range of 400 nm or longer but 700 nm or shorter, or light of 455 nm. The light in the wavelength range of 400 nm or longer but 700 nm or shorter and the light of 455 nm are both light generally used with projection image display devices.

The optical loss is preferably an optical loss of 1.0% or less with all wavelengths in the using wavelength band.

The optical loss of the optical element is preferably 1.0% or less relative to light having a wavelength of 455 nm.

The optical loss is preferably 1.0% or less relative to the light of any wavelength in the wavelength range of 450 nm or longer but 700 nm or shorter. Note that, the optical loss is smaller as a wavelength is longer.

The transmittance and reflectance of the optical element to the light at the using wavelength band can be determined by applying S-polarized light to the optical element with an incident angle of 5° to measure intensity of the transmitted light and intensity of the reflected light, and calculating the transmittance and reflectance using the measured values according to the following formulae.

Transmittance=intensity of transmitted light/intensity of incident light (%)

Reflectance=intensity of reflected light/intensity of incident light (%)

Optical loss (%)=100%−transmittance (%)−reflectance (%)

In the measurement above, the transmitted light to be measured is direct transmission light, and the reflected light to be measured is specular reflection light.

The transmittance of the optical element to the light at the using wavelength band and the reflectance of the optical element are, for example, measured by means of a spectrophotometer V-570, available from JASCO Corporation.

Examples of the optical element having the above-described structure include a retardation element configured to give a phase difference to incident light, and a retardation compensator element.

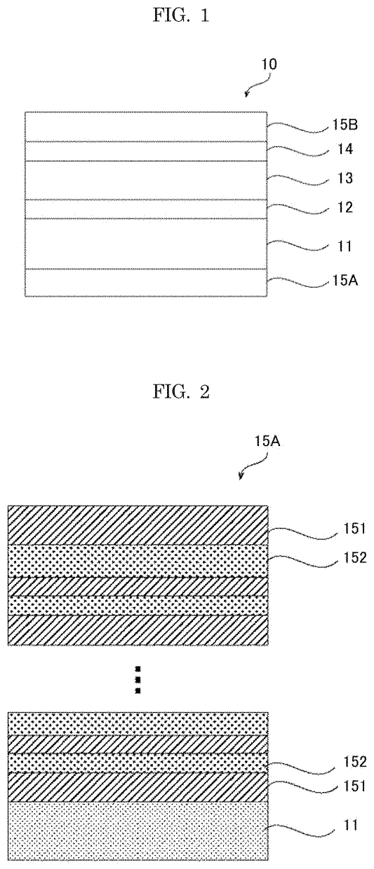

FIG. 1 is a cross-sectional view illustrating a configuration example of the optical element. As illustrated in FIG. 1, the optical element 10 includes a transparent substrate 11, a matching layer 12 disposed on the transparent substrate 11, where the matching layer includes high refractive index films and low refractive index films are alternately deposited, and a thickness of each film is equal to or less than a used wavelength, a birefringent layer 13 formed of an oblique angle vapor deposition film, disposed on the matching layer 12, and a protective layer 14 formed of a dielectric film formed on the birefringent layer 13. Moreover, the optical element includes a first antireflection layer 15A at the side of the transparent substrate 11, and a second antireflection layer 15B at the side of the protective layer 14.

### Transparent Substrate

The transparent substrate 11 is transparent to light at a using wavelength band. The transparent substrate 11 has high transmittance to the light at the using wavelength band. Examples of a material of the transparent substrate 11 include glass, quartz, crystal, and sapphire. A shape of the transparent substrate 11 is typically a square, but the shape thereof is appropriately selected depending on the intended purpose. A thickness of the transparent substrate 11 is, for example, preferably 0.1 mm or greater but 3.0 mm or less.

### Antireflection Layer

For example, the first antireflection layer 15A is disposed to be in contact with a surface of the transparent substrate 11 opposite to a surface thereof facing the side of the birefringent layer 13.

For example, the second antireflection layer 15B is optionally disposed to be in contact with a surface of the protective layer 14 opposite to a surface thereof facing the birefringent layer 13.

The antireflection layer 15A and the second antireflection layer 15B have an antireflection function in a desirable wavelength band for use.

FIG. 2 is a schematic cross-sectional view of the first antireflection layer. As illustrated in FIG. 2, the first antireflection layer 15A is a multilayer film where two or more inorganic oxide films having mutually different refractive indexes are deposited. For example, the first antireflection layer 15A is a multilayer film where first oxide films 151 and second oxide films 152 having mutually different refractive indexes are alternately deposited. The number of layers within the antireflection layer is appropriately determined according to the necessity, and the number of layers is preferably from about 5 layers to about 40 layers in view of productivity. Note that, the second antireflection layer 15B has the similar configuration to the first antireflection layer 15A.

The larger difference between the refractive index of the first oxide film 151 and the refractive index of the second oxide film 152 is more preferable. In view of readily availability of materials and film formability, the difference is preferably 0.5 or greater but 1.0 or less. The refractive index is, for example, a refractive index at a wavelength of 550 nm.

For example, the oxide films of the first antireflection layer 15A and the oxide films of the second antireflection layer 15B are each an oxide film including at least one selected from the group consisting of Ti, Si, Ta, Al, Ce, Zr, Nb, and Hf.

For example, the antireflection layer is a multiple film where first oxide films 151 formed of niobium oxide (refractive index at wavelength of 550 nm: 2.3) having a relatively high refractive index, and second oxide films 152 formed of silicon oxide (refractive index at wavelength of 550 nm: 1.5) having a relatively low refractive index are alternately deposited.

Note that, the oxides constituting the antireflection layer may be nonstoichiometric. Specifically, an atomic ratio of constitutional elements of the oxide is not necessarily a simple whole number ratio. When an oxide film is formed by sputtering etc., the formed oxide is often nonstoichiometric. Moreover, an elemental ratio of the oxide of the formed film cannot be easily measured stably, thus it is difficult to determine an elemental ratio of the oxide.

Considering the oxide being nonstoichiometric, for example, the oxide including Nb is represented by the following formula.

NbO_{X} (0<X≤2.5)

For example, the oxide including Si is represented by the following formula.

SiO_{Y} (0<Y≤2)

When the antireflection layer is formed, light absorption of the antireflection layer can be reduced, and an optical loss in the optical element can be declined by reducing oxygen deficiency of oxide formed.

A thickness of the antireflection layer is not particularly limited and may be appropriately selected depending on the intended purpose. For example, the thickness of the antireflection layer is 250 nm or greater but 2,300 nm or less. In the present specification, a thickness of a layer (film thickness) means an average film thickness.

### Matching Layer

The matching layer 12 is, for example, a multilayer film where two or more inorganic oxide films having mutually different refractive indexes are deposited. The matching layer 12 is disposed between the transparent substrate 11 and the birefringent layer 13. The matching layer 12 is designed to cancel interface reflection light by interference, to thereby prevent reflection at an interface between the transparent substrate 11 and the birefringent layer 13. Specifically, the matching layer 12 is designed to cancel out reflected light at an interface between the transparent substrate 11 and the matching layer 12 and reflected light at an interference between the matching layer 12 and the birefringent layer 13.

For example, the matching layer 12 is formed of an oxide film including at least one selected from the group consisting of Ti, Si, Ta, Al, Ce, Zr, Nb, and Hf.

Note that, the oxides constituting the matching layer 12 may be nonstoichiometric. Specifically, an atomic ratio of constitutional elements of the oxide is not necessarily a simple whole number ratio. When an oxide film is formed by sputtering etc., the formed oxide is often nonstoichiometric.

When the matching layer 12 is formed, light absorption of the matching layer 12 can be reduced, and an optical loss in the optical element can be declined by reducing oxygen deficiency of oxide formed.

A thickness of the matching layer 12 is not particularly limited and may be appropriately selected depending on the intended purpose. For example, the thickness of the matching layer 12 is 140 nm or greater but 240 nm or less.

### Birefringent Layer

The birefringent layer 13 is formed of an oblique angle vapor deposition film.

The birefringent layer 13 is a layer having a function of imparting a phase difference to the optical element of the present invention.

In the optical element 10 illustrated in FIG. 1, the birefringent layer 13 is disposed between the matching layer 12 and the protective layer 14.

The birefringent layer 13 includes, for example, a birefringent film formed of an inorganic material. The inorganic material is preferably a dielectric material. Examples of the inorganic material include an oxide including at least one selected from the group consisting of Si, Nb, Zr, Ti, La, Ta, Al, Hf, and Ce.

The inorganic material is preferably tantalum oxide (e.g., Ta₂O₅).

A thickness of the birefringent layer 13 is, for example, 200 nm or greater but 4,200 nm or less.

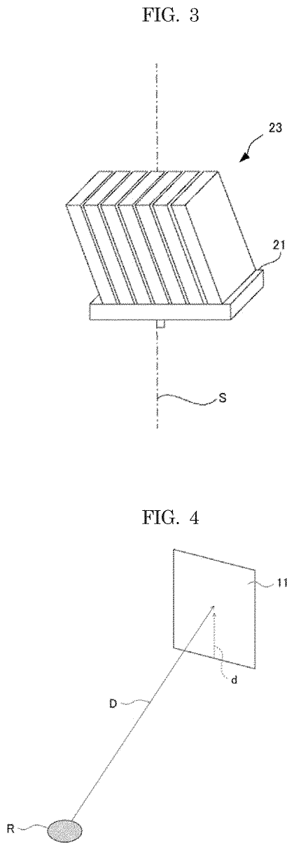

FIG. 3 is a perspective schematic view of an oblique angle vapor deposition film. As illustrated in FIG. 3, the oblique angle vapor deposition film 23 constituting the birefringent layer 13 is formed by depositing a deposition material in a direction slanting relative to a normal line S that is a direction perpendicular to a surface of the transparent substrate 11 or the deposition target surface 21. The slanted angle relative to the normal line S of the deposition target surface 21 is preferably 60° or greater but 80° or less.

The birefringent layer typically has a structure where a plurality of the above-described birefringent films are deposited.

Each birefringent film is formed by depositing in the direction slanting relative to the normal line S, and an angle formed between the film formation direction of an inorganic material constituting the birefringent film and a surface of the transparent substrate is not 90°.

A method creating a state where an angle formed between the film formation direction of the inorganic material and the surface of the transparent substrate is not 90° is, for example, preferably a method where a deposition source is arranged in a position slanted relative to the normal line S and an oblique angle vapor deposition film is formed by oblique angle vapor deposition from the deposition source. When a birefringent layer is formed by performing oblique angle vapor deposition multiple times, the oblique angle vapor deposition is repeated with varying the deposition angle to thereby obtain a final birefringent layer.

FIG. 4 is a schematic view illustrating one example of an oblique angle vapor deposition for forming the oblique angle vapor deposition film.

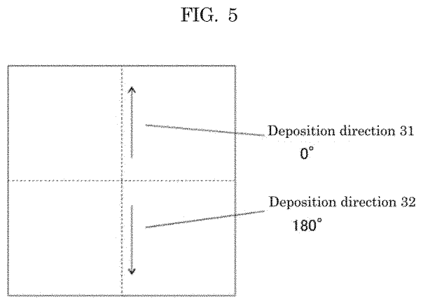

FIG. 5 is a schematic view illustrating one example of a direction (vapor deposition direction) projecting a flying direction of the deposition material from a vapor deposition source to a vapor deposition target surface.

As illustrated in FIG. 4, a linear direction for projecting a film formation direction of the birefringent film on a surface of the transparent substrate is represented by d, when an oblique angle vapor deposition film is formed on the transparent substrate 11 in the deposition direction D from the deposition source R.

As illustrated in FIGS. 4 and 5, a film formed by alternately forming oblique angle vapor deposition films is formed by alternately repeating a film formation performed by vapor deposition in the first vapor deposition direction 31, and film formation performed by vapor deposition in the second vapor deposition direction 32. Specifically, after forming a film by vapor deposition in the first vapor deposition direction 31, the vapor deposition target surface is rotated by 180° around a center line passing through a center of the vapor deposition surface in a vertical direction relative to the vapor deposition surface, to thereby perform film formation by vapor deposition from the second vapor deposition direction 32. By repeating the above-described processes, a film, in which first oblique angle vapor deposition films each having a first slanting direction relative to a normal line of the vapor deposition target surface, and second oblique angle vapor deposition films each having a second slanting direction relative to the normal line of the vapor deposition target surface are alternately formed, is obtained.

### Protective Layer

The protective layer 14 is formed of a dielectric film, and is disposed to be in contact with the oblique angle vapor deposition film of the birefringent layer 13. The presence of the protective layer 14 can prevent warping of the optical element 10, and can improve humidity resistance of the oblique angle vapor deposition film.

The dielectric material of the protective layer 14 is not particularly limited and may be appropriately selected depending on the intended purpose, as long as the dielectric material can adjust stress applied to the optical element 10, and can exhibit an effect of improving humidity resistance. Examples of such a dielectric material include oxide including at least one selected from the group consisting of Si, Ta, Ti, Al, Nb, and La, and MgF₂.

A thickness of the protective layer 14 is not particularly limited and may be appropriately selected depending on the intended purpose. The thickness of the protective layer 14 is, for example, 10 nm or greater but 100 nm or less.

### Production Method of Optical Element

Next, the production method of an optical element according to the present embodiment will be described.

In the production method of an optical element according to the present embodiment, the optical element according to the present embodiment is produced.

The production method of an optical element of the present embodiment includes forming antireflection layer or a matching layer, or both by reactive sputtering with setting an oxygen flow ratio to a predetermined range to produce an optical element having an optical loss of 1.0% or less relative to light at a using wavelength band.

The production method of an optical element according to the present embodiment preferably includes a step for forming an oxide film including Nb, or a step for forming an oxide film including Si, or both.

### Step for Forming Oxide Film Including Nb

In the production method of an optical element of the present embodiment, for example, an antireflection layer or a matching layer, or both include oxide including Nb.

The oxide film including Nb functions, for example, as a high refractive index layer in the antireflection layer or matching layer.

The production method of an optical element according to the present disclosure includes, for example, forming an oxide film including Nb using mixed gas including inert gas and oxygen gas by reactive sputtering using Nb as a target.

The oxygen flow ratio in the mixed gas when the oxide film including Nb is formed is preferably greater than 18%, where the oxygen flow ratio is represented by [oxygen gas flow rate/(inert gas flow rate+oxygen gas flow rate)]. When the oxygen flow ratio is greater than 18%, oxygen deficiency of the oxide in the antireflection layer or matching layer can be reduced, and hence light absorption of the antireflection layer or matching layer is low. As a result, an optical loss of the optical element can be easily kept low.

Moreover, the upper limit of the oxygen flow ratio is not particularly limited and may be appropriately selected depending on the intended purpose. For example, the upper limit thereof may be 30% or 25%. When the oxygen flow ratio is high, a film formation duration for forming an oxide film including Nb tends to be long. Therefore, the oxygen flow ratio is preferably 25% or less.

A unit of the inert gas flow rate and a unit of the oxygen gas flow rate are each a gas volume per unit time (e.g., mL/min).

### Step for Forming Oxide Film Including Si

In the production method of an optical element of the present embodiment, for example, the antireflection layer or matching layer, or both include an oxide including Si.

The oxide film including Si functions, for example, a low refractive index layer in the antireflection layer or matching layer.

The production method of an optical element of the present embodiment includes, for example, forming an oxide film including Si using mixed gas including inert gas and oxygen gas by reactive sputtering using Si as a target.

The oxygen flow ratio in the mixed gas when the oxide film including Si is formed is preferably greater than 8%, where the oxygen flow ratio is represented by [oxygen gas flow rate/(inert gas flow rate+oxygen gas flow rate)]. When the oxygen flow ratio is greater than 8%, oxygen deficiency of the oxide in the antireflection layer or matching layer can be reduced, and hence light absorption of the antireflection layer or matching layer is low. As a result, an optical loss of the optical element can be easily kept low.

Moreover, the upper limit of the oxygen flow ratio is not particularly limited and may be appropriately selected depending on the intended purpose. For example, the upper limit thereof may be 20% or 15%. When the oxygen flow ratio is high, a film formation duration for forming an oxide film including Si tends to be long. Therefore, the oxygen flow ratio is preferably 15% or less.

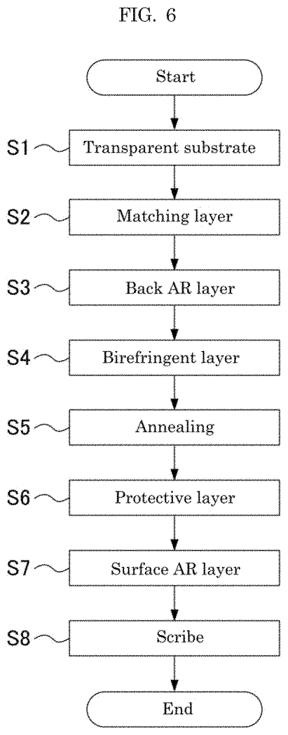

As a specific example of the production method of an optical element, the production method of an optical element having the configuration example illustrated in FIG. 1 will be described hereinafter. FIG. 6 is a flowchart depicting the production method of an optical element.

### <<S1>>

First, a transparent substrate 11 is provided in Step S1.

### <<S2>>

Next, a matching layer 12, in which oxide films are deposited, is formed on the transparent substrate in order to prevent reflection at an interface between the birefringent layer 13 and the transparent substrate 11 in Step S2.

During the formation of the matching layer 12, the matching layer 12 is formed by alternately performing a process for forming the above-described oxide film including Nb and a process for forming the above-described oxide film including Si. As a result, the matching layer 12 having low light absorption can be obtained.

### <<S3>>

Next, a first antireflection layer 15A [back antireflection (AR) layer] is formed on a surface of the transparent substrate 11, on which the matching layer 12 is not formed, in Step S3.

In the formation of the first antireflection layer 15A, the first antireflection layer 15A is formed by alternately performing the step for forming an oxide film including Nb and the step for forming an oxide film including Si. As a result, the first antireflection layer 15A having low light absorption can be obtained.

### <<S4>>

Next, a birefringent layer 13 is formed on the matching layer 12 by oblique angle vapor deposition in Step S4. As illustrated in FIGS. 4 and 5, for example, after performing film formation by vapor deposition in the first vapor deposition direction 31, the vapor deposition target surface is rotated by 180° around a center line passing through a center of the vapor deposition surface in a vertical direction relative to the vapor deposition surface, to thereby perform film formation by vapor deposition from the second vapor deposition direction 32. By repeating the above-described processes, a film, in which first oblique angle vapor deposition films each having a first slanting direction relative to a normal line of the vapor deposition target surface, and second oblique angle vapor deposition films each having a second slanting direction relative to the normal line of the vapor deposition target surface are alternately formed, is obtained.

### <<S5>>

Next, the birefringent layer 13 is subjected to annealing at a temperature of 200° C. or higher but 600° C. or lower in Step S5. The birefringent layer 13 is subjected to annealing more preferably at a temperature of 300° C. or higher but 500° C. or lower, further more preferably 400° C. or higher but 500° C. or lower. As a result, properties of the birefringent layer 13 can be stabilized.

### <<S6>>

Next, a protective layer 14 is formed on the birefringent layer 13 in Step S6. When a film of SiO₂ is formed as the protective layer 14, for example, tetraethoxysilane (TEOS) gas and O₂ are preferably used as a material of SiO₂, and a plasma CVD device is preferably used.

A SiO₂ CVD film formed by a plasma CVD device uses a vaporized material gas for film formation different from physical vapor deposition, such as sputtering. Therefore, TEOS gas is relatively easily penetrated into gaps in the column structure to further improve adhesion of the protective layer 14 to the birefringent layer 13.

### <<S7>>

Next, a second antireflection layer 15B (surface AR layer) is formed on the protective layer 14 in Step S7.

In the formation of the second antireflection layer 15B, the second antireflection layer 15B is formed by alternately performing the step for forming an oxide film including Nb and the step for forming an oxide film including Si. As a result, the second antireflection layer 15B having low light absorption can be obtained.

### <<S8>>

Finally, scribe cutting is performed to obtain a size matched to a specification in Step S8.

According to the production method as described above, an optical element having excellent durability against light of high luminance and high output emitted from a laser light source etc. can be obtained.

### Projection Image Display Device

Since the above-described optical element has excellent durability against light of high luminance and high output, a projection image display device including the optical element can be suitably used as a projector, such as a liquid crystal projector, a digital light processing (DLP) (registered trademark) projector, a liquid crystal on silicon (LCOS) projector, and a grating light valve (GLV) (registered trademark) projector.

Specifically, the projection image display device according to the present embodiment includes the optical element, a light modulator, a light source configured to emit light, and a projection optical system configured to project modulated light, where the light modulator and the optical element are disposed on a light path between the light source and the projection optical system.

### Light Modulator

Examples of the light modulator include a liquid crystal display device including a transmissive liquid crystal panel etc., a micro-mirror display device including a digital micro-mirror device (DMD) etc., a reflective liquid crystal display device including a reflective liquid crystal panel etc., and a one-dimensional diffraction display device including a one-dimensional light modulator (grating light valve [GLV]) etc.

In the projection image display device using the liquid crystal display device, for example, the liquid crystal display device includes at least a liquid crystal panel, a first polarizing plate, and a second polarizing plate, and may further include other members according to the necessity.

### Liquid Crystal Panel

The liquid crystal panel is not particularly limited. For example, the liquid crystal panel includes a substrate, and a VA-mode liquid crystal layer including liquid crystal molecules having pre-tilt relative to the orthogonal direction to the main surface of the substrate, and modulates the entered luminous flux entered. The VA-mode (vertical alignment mode) means a system where liquid crystal molecules aligned vertical (or with pre-tilt) to the substrate are moved using a longitudinal electric field in a vertical direction.

### First Polarizing Plate and Second Polarizing Plate

A first polarizing plate is a polarizing plate disposed at the inlet side of the liquid crystal panel, and a second polarizing plate is a polarizing plate disposed at the outlet side of the liquid crystal panel. The first polarizing plate and the second polarizing plate are preferably inorganic polarizing plates in view of durability.

### Optical Element

An optical element is the optical element of the present invention.

For example, the optical element is the optical element of the structural example illustrated in FIG. 1, and the optical element is disposed in a desirable position on a light path constituting the projection image display device.

In the projection image display device using the micro-mirror display device, the optical element is disposed on the same light path in combination with a diffuser, a polarization beam splitter, etc.

### Light Source

A light source is not particularly limited and may be appropriately selected depending on the intended purpose, as long as the light source is a member that emits light. Since the liquid crystal display device includes the optical element having excellent durability in the present embodiment, a laser light source that emits light of high luminance and high output can be used.

The wavelength of the laser light source is, for example, 455 nm.

### Projection Optical System

The projection optical system is not particularly limited and may be appropriately selected depending on the intended purpose, as long as the projection optical system is a member for projecting modulated light. Examples of the projection optical system include a projection lens configured to project the modulated light onto a screen.

The projection image display device having the above-described structure can display an image of high luminance and high output using light of high luminance and high output emitted from a laser light source etc.

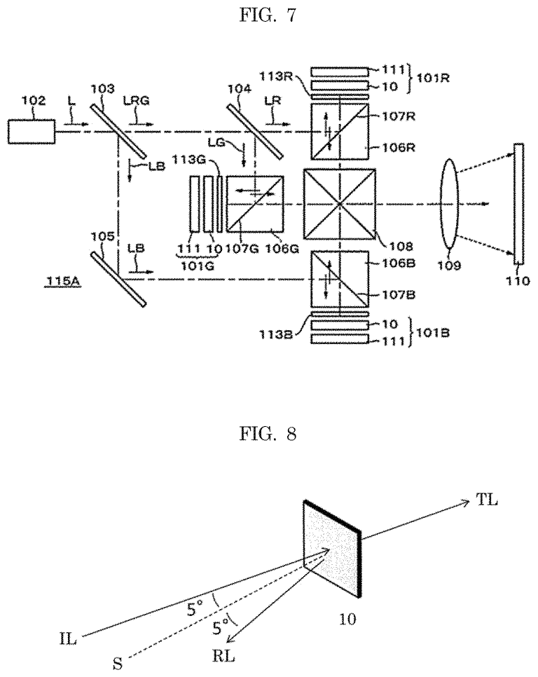

FIG. 7 is a schematic view illustrating one example of the structure of the projection image display device according to the present embodiment. The projection image display device 115A is a so-called 3-panel liquid crystal projector, which displays a color image using 3 liquid crystal panels of red, green, and blue. As illustrated in FIG. 7, the projection image display device 115A includes liquid crystal display devices 101R, 101G, and 101B, a light source 102, dichroic mirrors 103 and 104, a total reflection mirror 105, polarization beam splitters 106R, 106G, and 106B, a beam-combining prism 108, and a projection lens 109.

The light source 102 is configured to emit light-source light (white light) L including blue light LB, green light LG, and red light LR for forming an image display. Examples of the light source 102 include a halogen lamp, a metal halide lamp, a xenon lamp, and a laser light source.

The dichroic mirror 103 has a function of separating the light-source light L into blue light LB and light of other colors LRG. The dichroic mirror 104 has a function of separating the light passed LRG through the dichroic mirror 103 into red light LR and green light LG. The total reflection mirror 105 reflects the blue light LB separated by the dichroic mirror 103 towards the polarization beam splitter 106B.

The polarization beam splitters 106R, 106G, and 106B are prism-type polarized light separators disposed on light paths of the red light LR, the green light LG, and the blue light LB, respectively. The polarization beam splitters 106R, 106G, and 106B have polarized light splitting surfaces 107R, 107G, and 107B, respectively. The polarization beam splitters 106R, 106G, and 106B have a function of splitting the entered light of each color into two polarized light components orthogonal to each other at the polarized light splitting surfaces 107R, 107G, and 107B, respectively. The polarized light splitting surfaces 107R, 107G, and 107B reflect one polarized light component (e.g., an S-polarized light component) and transmit the other polarized light component (e.g., a P-polarized light component).

The color light of the certain polarized light component (e.g., an S-polarized light component) separated by each of the polarized light splitting surfaces 107R, 107G, and 107B of the polarization beam splitters 106R, 106G, and 106B enters each of the liquid crystal display devices 101R, 101G, and 101B. The liquid crystal display devices 101R, 101G, and 101B are driven by driving voltage applied according to an image signal to modulate the incident light, and also have a function of reflecting the modulated light to the polarization beam splitters 106R, 106G, and 106B.

The optical elements 10 and the ¼-wave plates 113R, 113G, and 113B are disposed between the polarization beam splitters 106R, 106G, and 106B, and the liquid crystal panels of the liquid crystal display devices 101R, 101G, and 101B, respectively. The ¼-wave plates 113R, 113G, and 113B each function as a ½-wave plate as the ¼-wave plates 113R, 113G, and 113B allow to pass the light twice, i.e., when the light enters the liquid crystal panel, and when the light is emitted from the liquid crystal panel (for example, converting an S-polarized light component into a P-polarized light). Moreover, the ¼-wave plates 113R, 113G, and 113B have a function of correcting a reduction of the contrast owing to the incident light angle dependency the polarization beam splitters 106R, 106G, and 106B have. The optical elements 10 have a function of compensating the residual phase difference of the liquid crystal panels constituting the liquid crystal display devices 101R, 101G, and 101B, respectively. In one aspect, the ¼-wave plate is the optical element of the present embodiment. In another aspect, moreover, the optical element 10 is the optical element of the present embodiment.

The beam-combining prism 108 has a function of combining color light of the certain polarized light components (e.g., P-polarized light components) emitted from the liquid crystal display devices 101R, 101G, and 101B and passed through the polarization beam splitter 106R, 106G, and 106B. The projection lens 109 has a function of projecting the synthesized light emitted from the beam-combining prism 108 towards the screen 110.

Next, an operation of the projection image display device 115A constituted in the above-described manner will be described.

First, white light L emitted from the light source 102 is split into blue light LB and other color light (red light and green light) LRB by a function of the dichroic mirror 103. The blue light LB is reflected to the polarization beam splitter 106B by a function of the total reflection mirror 105.

Meanwhile, other color light (red light and green light) LRG is further split into red light LR and green light LG by a function of the dichroic mirror 104. The split red light LR and green light LG enters the polarization beam splitters 106R and 106G, respectively.

The polarization beam splitters 106R, 106G, and 106B are configured to split the entered color light into two polarized light components orthogonal to each other by the polarized light splitting surfaces 107R, 107G, and 107B, respectively. The polarized light splitting surfaces 107R, 107G, and 107B reflect one polarized light component (e.g., an S-polarized light component) to the liquid crystal display devices 101R, 101G, and 101B. The liquid crystal display devices 101R, 101G, and 101B are driven by driving voltage applied according to an image signal, and modulate color light of the entered certain polarized light by pixel.

The liquid crystal display devices 101R, 101G, and 101B reflect the modulated color light to the polarization beam splitters 106R, 106G, and 106B, respectively. The polarization beam splitters 106R, 106G, and 106B only pass through the certain polarized light component (e.g., P-polarized light components) within the reflected light (modulated light) from the liquid crystal display devices 101R, 101G, and 101B, and emit towards the beam-combining prism 108.

The beam-combining prism 108 synthesize the color light of the certain polarized light components passed through the polarization beam splitters 106R, 106G, and 106B, and emits towards the projection lens 109. The projection lens 109 projects the synthesized light emitted from the beam-combining prism 108 to the screen 110. As a result, an image corresponding to the light modulated by the liquid crystal display devices 101R, 101G, and 101B is projected on the screen 110, and a desired image display is achieved.

### EXAMPLES

Specific example of the present invention will be described hereinafter. However, the present invention is not limited to the example below. Note that, formed films are described as a SiO₂ film and a Nb₂O₅ film for the matter of convenience, but the films are highly likely nonstoichiometric.

### Example 1

### Production of Optical Element

On one surface of a glass substrate (average thickness: 0.7 mm), a SiO₂ film and an Nb₂O₅ film were alternately deposited to form 5 layers in total by sputtering to thereby form a matching layer.

The SiO₂ film was formed by reactive sputtering using a Si target with introducing Ar gas and O₂ gas. The O₂ gas flow ratio was set to 12%.

Note that, the O₂ gas flow ratio can be determined as follows.

O₂ gas flow ratio=O₂ gas flow rate/(Ar gas flow rate+O₂ gas flow rate)

The Nb₂O₅ film was formed by reactive sputtering using an Nb target with introducing Ar gas and O₂ gas. The O₂ gas flow ratio was 22%.

Subsequently, on the other surface of the glass substrate, an Nb₂O₅ film and a SiO₂ film were alternately deposited to form 7 layers in total by sputtering to thereby form an antireflection layer.

The SiO₂ film was formed by reactive sputtering using a Si target with introducing Ar gas and O₂ gas. The O₂ gas flow ratio was set to 12%.

The Nb₂O₅ film was formed by reactive sputtering using an Nb target with introducing Ar gas and O₂ gas. The O₂ gas flow ratio was 22%.

Subsequently, a deposition source was arranged in a position slanted relative to a normal line of the glass substrate by 70°, and oblique angle vapor deposition was performed on the matching layer using a Ta₂O₅ deposition material with alternating between a first vapor deposition direction of 0°, and a second vapor deposition direction of 180° to thereby obtain a birefringent layer formed of an oblique angle vapor deposition film.

After the vapor deposition, annealing was performed at 400° C. to stabilize the properties of the birefringent layer. After the annealing, a SiO₂ film was formed by plasma CVD using tetraethoxysilane (TEOS) gas and O₂.

Subsequently, an Nb₂O₅ film and a SiO₂ film were alternately deposited to form 7 layers in total by sputtering to thereby form an antireflection layer.

The SiO₂ film was formed by reactive sputtering using a Si target with introducing Ar gas and O₂ gas. The O₂ gas flow ratio was set to 12%.

The Nb₂O₅ film was formed by reactive sputtering using an Nb target with introducing Ar gas and O₂ gas. The O₂ gas flow ratio was 22%.

In the manner as described above, an optical element was obtained.

### Comparative Example 1

An optical element was produced in the same manner as in Example 1, expect that the O₂ gas flow ratio was changed to 8% for the formation of the SiO₂ film and the O₂ gas flow ratio was changed to 18% for the formation of the Nb₂O₅ film during formation of the matching layer and the antireflection layer.

### Measurements of Transmittance and Reflectance

As illustrated in FIG. 8, S-polarized light having wavelengths of 400 nm to 700 nm was applied at an incidence angle of 5°, and the intensity of the transmitted light and the intensity of the reflected light were measured to calculate transmittance and reflectance. In FIG. 8, IL is incident light, S is a normal line, RL is reflected light, 10 is an optical element, and TL is transmitted light.

Transmittance=intensity of transmitted light/intensity of incident light (%)

Reflectance=intensity of reflected light/intensity of incident light (%)

Optical loss (%)=100%−transmittance (%)−reflectance (%)

As a result of the measurements performed on 30 samples, the optical loss of the samples of Example 1 was from 0.5% to 0.9%, and the optical loss of the samples of Comparative Example 1 was from 1.2% to 1.6%.

Moreover, one transmittance, one reflectance, and one optical loss of the sample of Example 1 are presented in Figures.

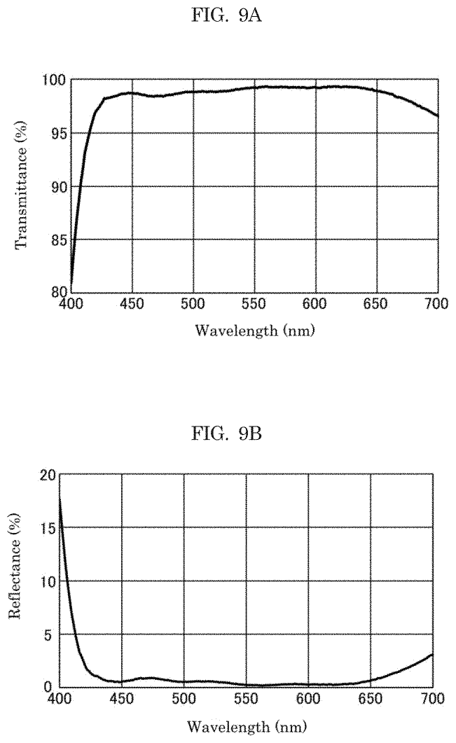

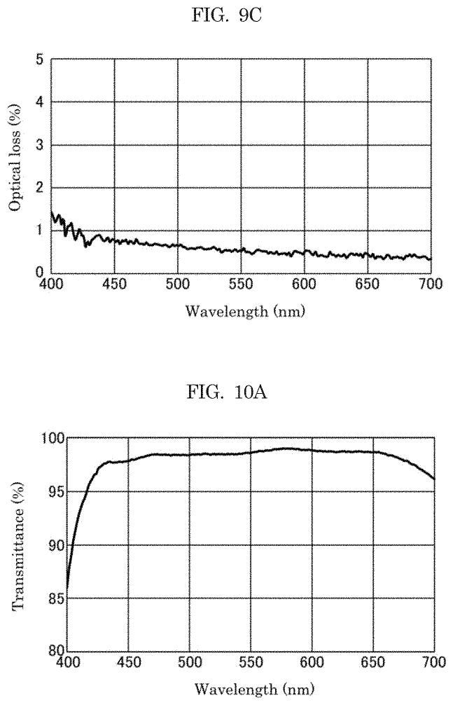

FIG. 9A is a graph depicting one transmittance of the sample of Example 1.

FIG. 9B is a graph depicting one reflectance of the sample of Example 1.

FIG. 9C is a graph depicting one optical loss of the sample of Example 1.

Moreover, one transmittance, one reflectance, and one optical loss of the sample of Comparative Example 1 are presented in Figures.

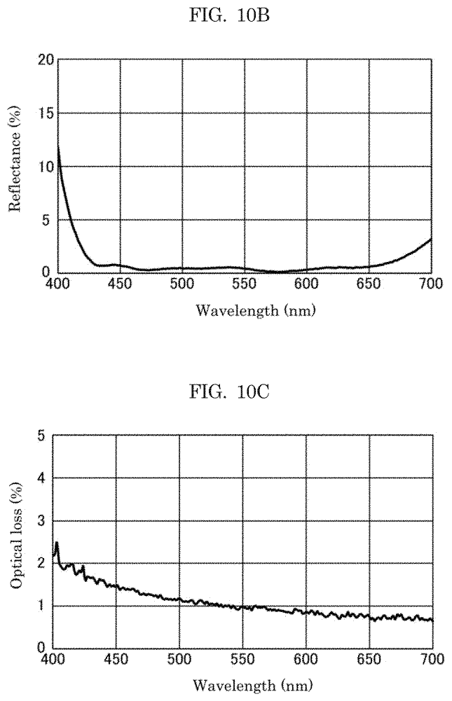

FIG. 10A is a graph depicting one transmittance of the sample of Comparative Example 1.

FIG. 10B is a graph depicting one reflectance of the sample of Comparative Example 1.

FIG. 10C is a graph depicting one optical loss of the sample of Comparative Example 1.

### Laser Irradiation Test

Laser irradiation conditions
Wavelength: 455 nm-CW
Laser power: 50 W
Power density: 8.3 W/mm²
Irradiation duration: 3 minutes

Thirty samples of each of Example 1 and Comparative Example 1 were irradiated with laser under the above-described laser irradiation conditions, and the presence of damages was visually observed. The results are presented below.

Example 1: the number of damages [0]/the number of tests [30]

Comparative Example 1: the number of damages [10]/the number of tests [30]

It was found that there was no damage from the laser irradiation test and excellent durability against laser was obtained when the optical loss was 1.0% or less.

### INDUSTRIAL APPLICABILITY

Since the optical element of the present invention has excellent durability even when a laser light source is used, the optical element is suitably used for a projection image display device using a laser light source.

What is claimed is:

1. An optical element, comprising:
a substrate that is transparent to light at a using wavelength band;
an antireflection layer;
a matching layer; and
a birefringent layer formed of an oblique angle vapor deposition film,
wherein an optical loss in the optical element at the using wavelength band is 1.0% or less, and
the optical loss is calculated using the following formulae from intensity of transmitted light and intensity of reflected light measured by S-polarized light at an incident angle of 5° in the optical element,
Transmittance=intensity of transmitted light/intensity of incident light (%)
Reflectance=intensity of reflected light/intensity of incident light (%)
Optical loss (%)=100%−transmittance (%)−reflectance (%).

2. The optical element according to claim 1,
wherein the optical loss in the optical element at a wavelength of 455 nm is 1.0% or less.

3. The optical element according to claim 1,
wherein the antireflection layer is a multilayer film in which two or more inorganic oxide films having mutually different refractive indexes are deposited.

4. The optical element according to claim 3,
wherein at least one of the inorganic oxide films includes at least one selected from the group consisting of Ti, Si, Ta, Al, Ce, Zr, Nb, and Hf.

5. The optical element according to claim 4,
wherein at least one of the inorganic oxide films includes Nb.

6. The optical element according to claim 4,
wherein at least one of the inorganic oxide films includes Si.

7. The optical element according to claim 4,
wherein the antireflection layer is a multilayer film in which an inorganic oxide film including Nb and an inorganic oxide film including Si are deposited.

8. The optical element according to claim 1,
wherein the matching layer is a multilayer film in which two or more inorganic oxide films having mutually different refractive indexes are deposited.

9. The optical element according to claim 8,
wherein at least one of the inorganic oxide films includes at least one selected from the group consisting of Ti, Si, Ta, Al, Ce, Zr, Nb, and Hf.

10. The optical element according to claim 9,
wherein at least one of the inorganic oxide films includes Nb.

11. The optical element according to claim 9,
wherein at least one of the inorganic oxide films includes Si.

12. The optical element according to claim 9,
wherein the matching layer is a multilayer film in which an inorganic oxide film including Nb and an inorganic oxide film including Si are deposited.

13. The optical element according to claim 1,
wherein the antireflection layer is disposed on both sides of the substrate.

14. A production method of an optical element, comprising:
providing a substrate that is transparent to light at a using wavelength band;
forming at least one antireflection layer;
forming a matching layer; and
forming a birefringent layer formed of an oblique angle vapor deposition film,
wherein an optical loss in the optical element at the using wavelength band is 1.0% or less,
the antireflection layer or the matching layer, or both are formed by reactive sputtering, and
the optical loss is calculated using the following formulae from intensity of transmitted light and intensity of reflected light measured by S-polarized light at
an incident angle of 5° in the optical element,
Transmittance=intensity of transmitted light/intensity of incident light (%)
Reflectance=intensity of reflected light/intensity of incident light (%)
Optical loss (%)=100%−transmittance (%)−reflectance (%).

15. The production method according to claim 14,
wherein the reactive sputtering is reactive sputtering using mixed gas including inert gas and oxygen gas, and
an oxygen flow ratio in the mixed gas is set in a manner that the optical loss of the optical element is to be 1.0% or less relative to the light at the using wavelength band.

16. The production method according to claim 14,
wherein the forming at least one antireflection layer, the forming a matching layer, or both include laminating two or more inorganic oxide films having mutually different refractive indexes by reactive sputtering to form a multilayer film.

17. The production method according to claim 14,
wherein the forming at least one antireflection layer or the forming a matching layer, or both include forming an oxide film including Nb using mixed gas including inert gas and oxygen gas by reactive sputtering using Nb as a target, and
wherein an oxygen flow ratio in the mixed gas is greater than 18% when the oxide film including Nb is formed, where the oxygen flow ratio is represented by [an oxygen flow rate/(an inert gas flow rate+the oxygen gas flow rate)].

18. The production method according to claim 14,
wherein the forming at least one antireflection layer or the forming a matching layer, or both include forming an oxide film including Si using mixed gas including inert gas and oxygen gas by reactive sputtering using Si as a target, and
wherein an oxygen flow ratio in the mixed gas is greater than 8% when the oxide film including Si is formed, where the oxygen flow ratio is represented by [an oxygen flow rate/(an inert gas flow rate+the oxygen gas flow rate)].

19. A projection image display device, comprising:
an optical element;
a light modulator;
a light source configured to emit light; and
a projection optical system configured to project modulated light,
wherein the light modulator and the optical element are disposed on a light path between the light source and the projection optical system, and
wherein the optical element includes:
a substrate that is transparent to light at a using wavelength band;
an antireflection layer;
a matching layer; and
a birefringent layer formed of an oblique angle vapor deposition film,
wherein an optical loss in the optical element at the using wavelength band is 1.0% or less, and
the optical loss is calculated using the following formulae from intensity of transmitted light and intensity of reflected light measured by S-polarized light at an incident angle of 5° in the optical element,
Transmittance=intensity of transmitted light/intensity of incident light (%)
Reflectance=intensity of reflected light/intensity of incident light (%)
Optical loss (%)=100%−transmittance (%)−reflectance (%).
